(19) United States
(12) Patent Application Publication
(10) Pub. No.: US 2008/0285249 A1
(43) Pub. Date: Nov. 20, 2008

(54) Retention device for interface card cradle

(75) Inventor: Quie-Wau Chen, Taipei (TW)

Correspondence Address: Muncy, Geissler, Olds & Lowe, PLLC, P.O. BOX 1364, FAIRFAX, VA, 22038-1364, US

(73) Assignee: INVENTEC CORPORATION

(21) Appl. No.: 11/798,881

(22) Filed: May 17, 2007

(51) Int. Cl. H05K 7/14

(52) U.S. Cl. 361/801

(57) ABSTRACT

A retention device for an interface card cradle is provided for retaining an interface card cradle in a case of a computer. The retention device includes a guiding seat fixed to the case, a guided member, and a latching member. The guided member is connected to the interface card cradle and guided by the guiding seat, so as to move the interface card cradle relative to the guiding seat. The latching member is pivotally connected to the guiding seat, for selectively fixing the interface card cradle at a retained position or a released position.

### BACKGROUND OF THE INVENTION

1. Field of Invention

The present invention relates to the retention of an interface card cradle, and more particularly to a retention device for retaining an interface card cradle at different positions inside a case of a computer.

2. Related Art

Currently, with rapid development of technology and information, computers have become wide used instruments. A computer peripheral device, for example, peripheral component interconnect card (PCI card), in a computer, such as desktop computer, notebook, or server, must be electrically connected to the computer, so as to realize communication or signal transmission between the computer and the computer peripheral device, thereby achieving a preset function of the computer peripheral device.

The current retention method for an interface card in a server computer such as a blade server, an interface card cradle is used to be disposed in the case of the server computer, and a raiser card with a plurality of slots is fixed in the interface card cradle. For example, U.S. Pat. No. 6,373,691 has disclosed an interface card cradle. One of more interface card is fixed in the interface card cradle, and is electrically connected to each slot of the raiser card. Then, the interface card cradle is fixed at a predetermined position inside the case by screws, and the raiser card is electrically connected to the motherboard, so as to electrically connect the interface card to the motherboard. However, during the assemble/disassemble of the interface card, it costs a lot of time to tighten or release screws for fixing or removing the interface card cradle, which increase the time for replacing the interface card. Meanwhile, the screws may easily drop to the motherboard easily, thus resulting in short circuit and damage of the motherboard. In addition, according to the above design, during the assemble/disassemble of the interface card, the entire interface card cradle must be taken out of the case. No mechanism is provided for placing the interface card cradle temporarily for assembling/disassembling the interface card, which is also inconvenient in use.

### SUMMARY OF THE INVENTION

In view of the above problems, the object of the present invention is to provide a retention device for an interface card cradle, which can be quickly retained in a case of a computer, and can be temporarily retained at a predetermined position is the case during installing or removing the interface cards.

To achieve the aforementioned object, the retention device for an interface card cradle is provided for retaining an interface card cradle in a case of a computer. The retention device includes a guiding seat, a guided member, and a latching member. The guiding seat is fixed to the case, and the guiding seat has a containing space defined therein and at least one slide surface. The guided member is connected to the interface card cradle, and movably clamps on the sliding surface of the guiding seat, such that the guided member is guided by the guiding seat to move the interface card cradle relative to the guiding seat. The latching member is located in the containing space and pivotally connected to the guiding seat, wherein the latching member is selectively rotated to a first position or a second position, so as to fixing the interface card cradle to a retained position or an released position for the user to install or remove the interface cards.

The advantage of the present invention is that the interface card cradle is guided by the guided member to generate displacement and be fixed at a retained position or an released position, such that the user can quickly install or remove the interface card to be replaced without removing multiple screws or taking the entire interface card cradle out of the case.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1A is a exploded view of a latching mechanism according to an embodiment of the present invention;

FIG. 1B is a exploded view according to the embodiment of the present invention;

FIG. 2A is a perspective view according to the embodiment of the present invention;

FIG. 2B is a side view of FIG. 2A;

FIG. 3A is a perspective view of an interface card cradle fixed at a retained position according to the embodiment of the present invention;

FIG. 3B is a side view of the interface card cradle fixed at the retained position according to the embodiment of the present invention;

FIG. 4A is a perspective view of the interface card cradle fixed at an released position according to the embodiment of the present invention;

FIG. 4B is a side view of the operation of fixing the interface card cradle at the released position according to the embodiment of the present invention; and

FIG. 4C is a side view of the operation of fixing the interface card cradle at the released position according to the embodiment of the present invention.

### DETAILED DESCRIPTION OF THE INVENTION

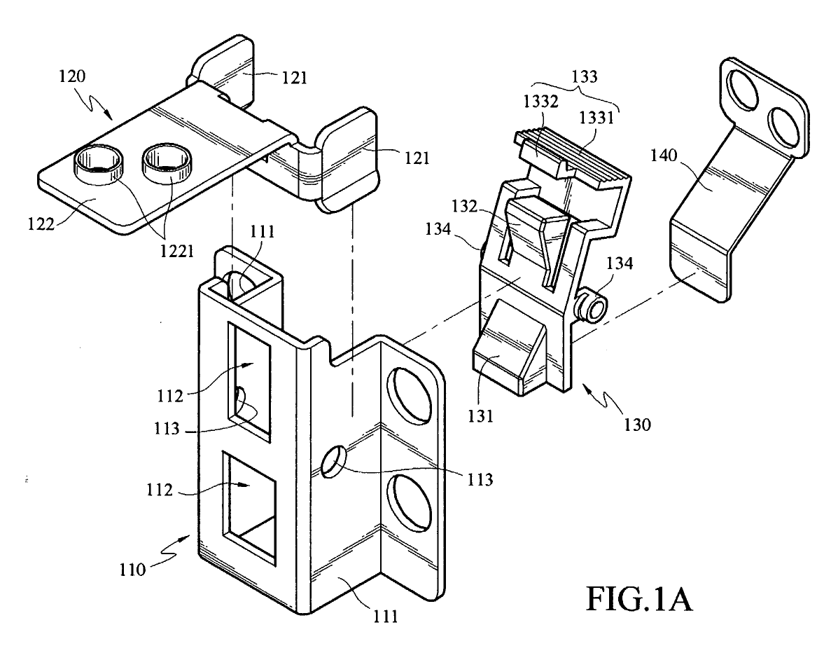

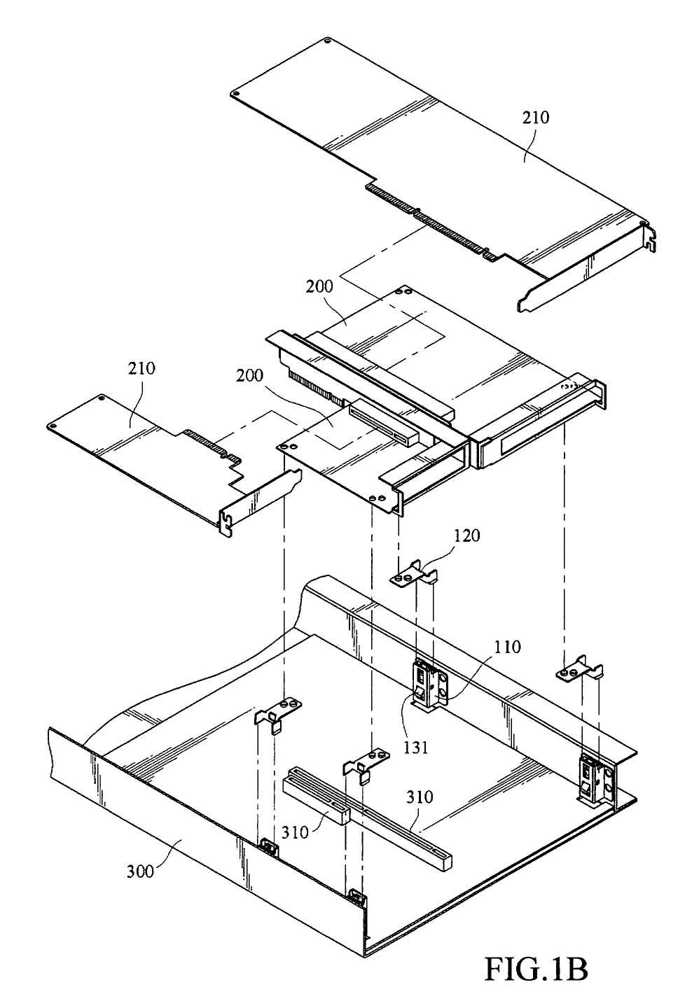

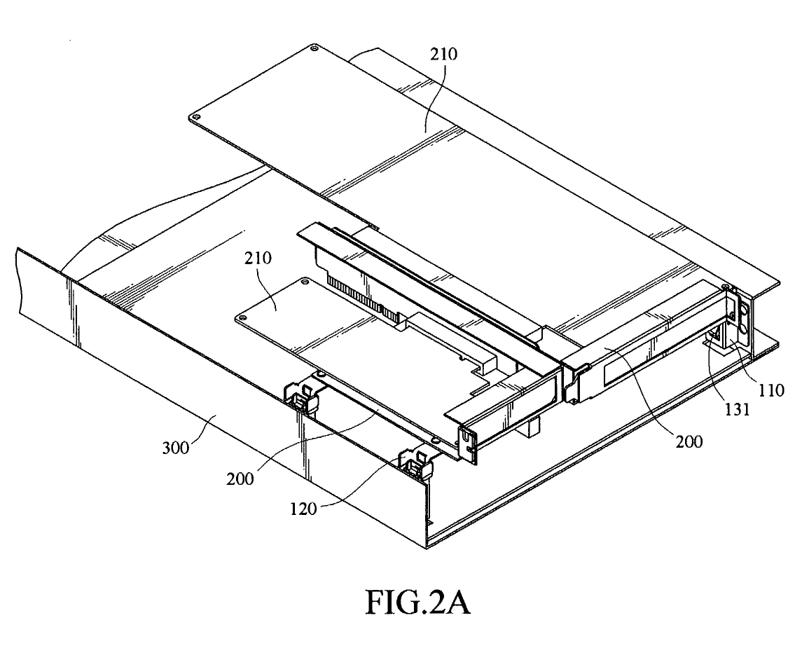

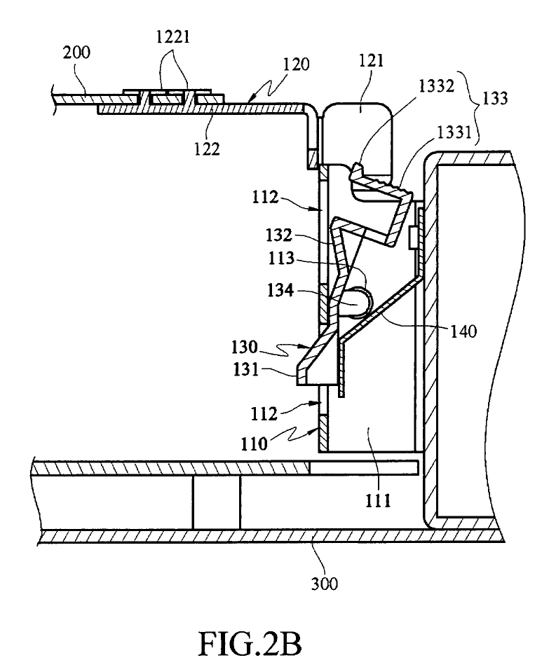

Referring to FIGS. 1A, 1B, 2A, and 2B, a plurality of retention devices according to an embodiment of the present invention are provided, wherein the retention devices are used for retaining an interface card cradle 200 in a case 300 of a computer. Each retention device includes a guiding seat 110, a guided member 120, and a latching member 130. The guiding seat 110 is fixed to an inner side of the case 300, and the guiding seat 110 has a cross-sectional area in the shape of U, such that a hollow containing space is defined in the guiding seat 110. Further, the guiding seat 110 has two sliding surfaces 111 formed at two sides of the guiding seat 110.

The guided member 120 has two gripping arms 121 and a joint portion 122. The joint portion 122 is formed at one end of the guided member 120, and at least one pillar 1221 is disposed on and protrudes on the joint portion 122 so as to be engaged within a fixing hole in the interface card cradle 200, so that the guided member 120 is securely connected to the interface card cradle 200. The two gripping arms 121 extend from the other end of the guided member 120, and clamp the guiding seat 110 with the two guided member 120 in contact with the two sliding surfaces 111 of guiding seat 110, so that the guided member 120 is movably disposed on the guiding seat 110. As such, the guided member 120 is guided by the guiding seat 110 to slide on the guiding seat 110 for moving the interface card cradle 200 relative to the guiding seat 110. The guided member 120 is used to make the interface card cradle 200 moving straightly relative to the guiding seat 110. The latching member 130 is pivotally connected to the guiding seat 110 and located in the containing space of, and can be selectively rotated to a first position or a second position.

The guiding seat 110 has two opposite pivot holes 113, respectively disposed on the sliding surfaces 111. The latching member 130 has two coaxial pivot shafts 134 extending in opposite directions to be respectively inserted in the pivot holes 113, such that the latching member 130 is pivotally connected to the guiding seat 110 and located in hollow containing space defined in the guiding seat 110, so as to be selectively rotated to the first position or the second position. The latching member 130 has a first latching portion 131 and a second latching portion 132. The first latching portion 131 is located at the lower portion of the latching member 130, and the second latching portion 132 is located at the upper portion of the latching member 130. The guiding seat 110 has two openings 112 respectively corresponding to the first latching portion 131 and the second latching portion 132. When the latching member 130 pivotally connected to the guiding seat 110 is rotated to the first position, the first latching portion 131 is moved with the latching member 130 to stand out of the corresponding opening 112 for fixing the interface card cradle 200 at a retained position. When the latching member 130 is rotated to the second position, the second latching portion 132 is moved to stand out of the corresponding opening 112 for fixing the interface card cradle 200 at a released position.

Further, the retention device includes a spring member 140, disposed in the guiding seat 110. One end of the spring member 140 is connected to the case 300, and the other end presses against the latching member 130 for push the latching member 130, so as to maintain the latching member 130 at the first position, and make the first latching portion 131 standing out of the corresponding opening 112 of the guiding seat 110.

Referring to FIGS. 1A, 1B, 2A, and 2B, the latching member 130 further has a coupling portion 133, formed at one end of the latching member 130 and corresponding to the second latching portion 132, wherein the coupling portion 133 is used for being engaged with the opening 112 corresponding to the second latching portion 132. The coupling portion 133 has a deformable pressing end 1331 and a hook 1332. The pressing end 1331 can be deformed by press, so as to make the coupling portion 133 elastically deformed, and the hook 1332 is formed at the pressing end 1332 for hooking the opening 112 corresponding to the second latching portion 132.

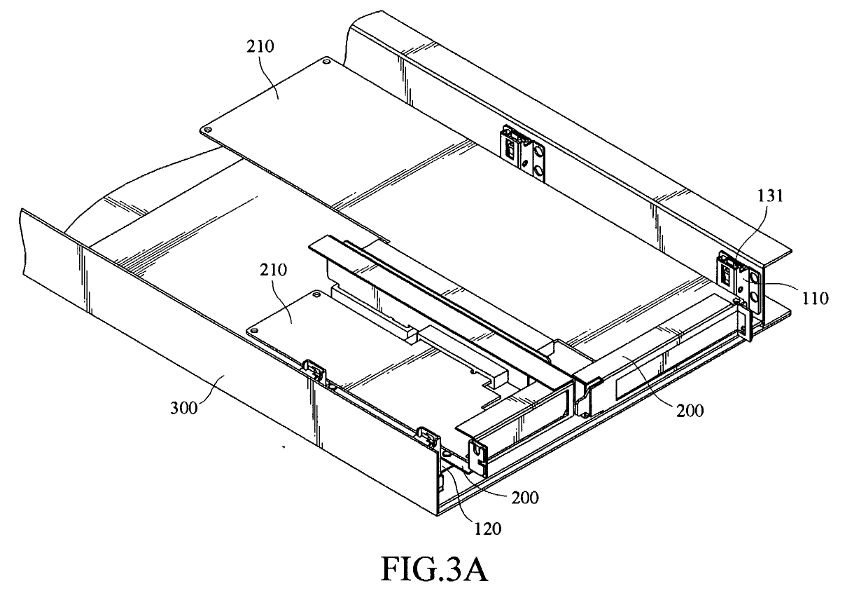

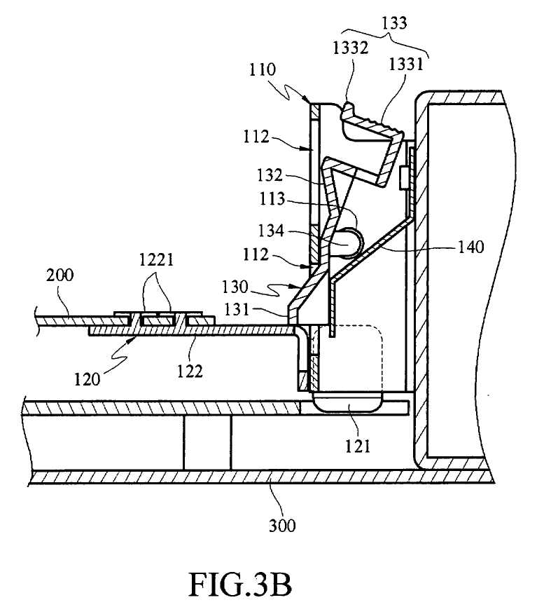

Referring to FIGS. 3A and 3B, the interface card cradle 200 with an interface card 210 is driven by the guiding seat 110 downwards to a retained position through the guided member 120. At same time, the first latching portion 131 standing out of the opening 112 at the lower portion of the guiding seat 110 pushes the spring member 140 backwards into the guiding seat 110 under the pressing force of the guided member 120. When the interface card cradle 200 reaches the retained position, the interface card 210 is inserted into a slot 310. Meanwhile, the force pressing the first latching portion 131 is removed, such that the spring member 140 push the first latching portion 131 to stand out of the corresponding opening 112 and presses against the upper end of the guided member 120, and thus the interface card cradle 200 is maintained at the retained position.

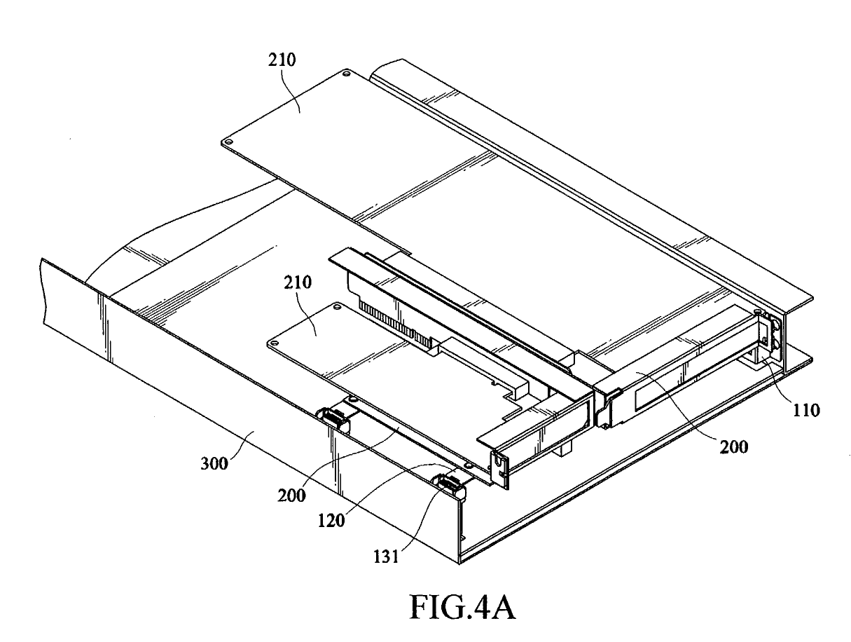

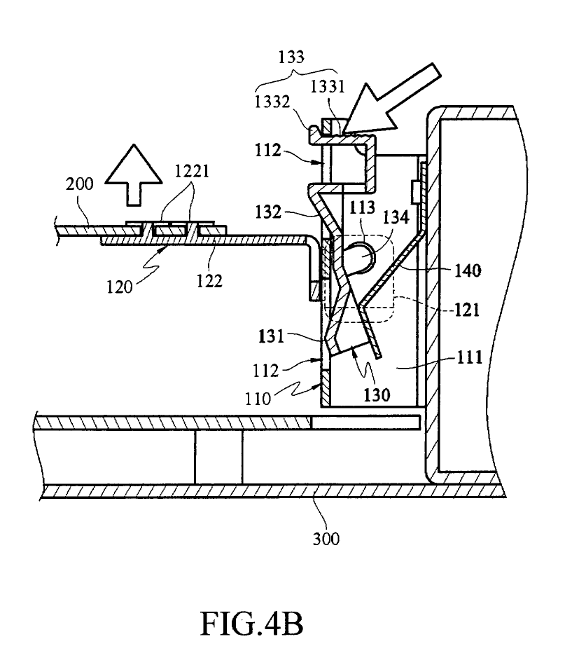

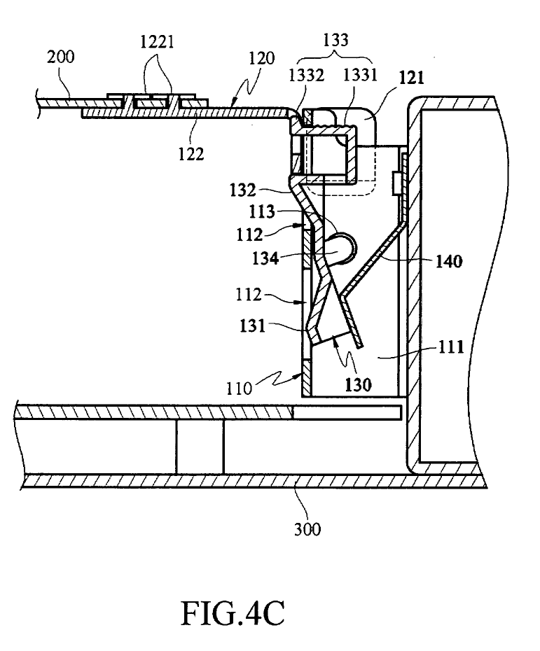

Referring to FIGS. 4A, 4B, and 4C, the coupling portion 133 of the latching member 130 is pulled to move forward and drive the second latching portion 132 to stand out of the guiding seat 110 through the corresponding opening 112, so that the hook 1332 of the coupling portion 133 hooks the opening 112 at the upper portion of the guiding seat 110 to keep the latching member 130 at the second position. At the same time, the first latching portion 131 located on the guided member 120 moves inward, such that the guided member 120 can slide upward along the guiding seat 110 freely and guides the interface card cradle 200 to be moved upward to a released position. The pressing end 1331 of the coupling portion 133 provides an elastic deformation range to make the interface card cradle 200 pass through the second latching portion 132, and to make the interface card cradle 200 to be maintained at the released position by the second latching portion 132, thus facilitating the user to assemble/disassemble the interface card 210.

According to the positioning mechanism disclosed by the present invention, the guided member can drive the interface card cradle to move along the guiding seat, and fix the interface card cradle at the retained position or the released position through the positioning function of the latching member. As such, the user can quickly assemble/disassemble the interface card without removing multiple screws or taking the entire interface card cradle out of the case.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A retention device for an interface card cradle, for retaining an interface card cradle in a case of a computer, comprising:
a guiding seat, fixed to the case;
a guided member, connected to the interface card cradle, and guided by the guiding seat, for moving the interface card cradle relative to the guiding seat; and
a latching member, pivotally connected to the guiding seat, for selectively being rotated to a first position for fixing the interface card cradle at a retained position; or being rotated a second position for fixing the interface card cradle at an released position.

2. The retention device for the interface card cradle as claimed in claim 1, further comprising at least one spring member, disposed in the guiding seat, wherein one end of the spring member is connected to the case, and the other end pressing against the latching member to maintain the latching member at the first position.

3. The retention device for the interface card cradle as claimed in claim 1, wherein the latching member further comprises a first latching portion and a second latching portion, and the guiding seat has two openings corresponding to the first latching portion and the second latching portion;
when the latching member is rotated to the first position, the first latching portion is moved to stand out of the corresponding opening; and
when the latching member is rotated to the second position, the second latching portion is moved to stand out of the corresponding opening.

4. The retention device for the interface card cradle as claimed in claim 3, wherein the latching member has a coupling portion, formed at one end of the latching member and corresponding to the second latching portion, and the coupling portion is used for being engaged with the opening corresponding to the second latching portion, so as to fix the latching member at the second position.

5. The retention device for the interface card cradle as claimed in claim 4, wherein the coupling portion has a deformable pressing end to be deformed; and a hook, formed at the pressing end, for hooking the opening corresponding to the second latching portion.

6. The retention device for the interface card cradle as claimed in claim 1, wherein the guiding seat further has two opposite pivot holes and the latching member has two coaxial pivot shafts extending in opposite directions which are respectively inserted in the two pivot holes.

7. The retention device for the interface card cradle as claimed in claim 1, wherein the guided member has two gripping arms for clamping guiding seat, and a joint portion connected to the interface card cradle.

8. The retention device for the interface card cradle as claimed in claim 7, wherein the joint portion further has at least one pillar protruded thereon, and the guided member is fixed to the interface card cradle by the pillar engaged within a fixing hole of the interface card cradle.
